(19) United States
(12) Patent Application Publication
(10) Pub. No.: US 2016/0293882 A1
(43) Pub. Date: Oct. 6, 2016

(54) OLED Illuminating Device

(71) Applicant: Ultimate Image Corporation, Miaoli City (TW)

(72) Inventor: Chih-Feng Sung, Miaoli City (TW)

(21) Appl. No.: 14/676,054

(22) Filed: Apr. 1, 2015

(51) Int. Cl. H01L 51/52

(52) U.S. Cl. CPC H01L 51/5246; H01L 51/5237; H01L 2251/558; H01L 2251/5361

(57) ABSTRACT

An OLED illuminating device includes: an OLED illuminating panel having opposite first and second outer surfaces, and a peripheral surface that interconnects the first and second outer surfaces, the first outer surface having a transparent region and a peripheral region that surrounds the transparent region; and at least one protective adhesive tape that extends from the peripheral region to the second outer surface along the peripheral surface of the OLED illuminating panel.

### FIELD

This disclosure relates to an illuminating device, more particularly to an OLED illuminating device.

### BACKGROUND

A conventional organic light-emitting diode illuminating panel (hereinafter referred to as OLED illuminating panel) includes two spaced-apart glass plates and an OLED layer disposed between the glass plates. Since the glass plates are fragile by nature, great care must be taken when fitting the OLED illuminating panel into a light fixture to prevent cracking of the OLED illuminating panel. However, such cracking of the OLED illuminating panel may still occur during transport.

Referring to FIGS. 1 and 2, in order to prevent the aforesaid problems, an OLED illuminating panel 8 may be disposed in a plastic frame 9 that has a transparent portion 91. The OLED illuminating panel 8 is then fitted into the light fixture along with the plastic frame 9. However, the plastic frame 9 not only causes the overall size and thickness of the light fixture to be increased, but also increases manufacturing costs.

### SUMMARY

Therefore, an object of the disclosure is to provide an OLED illuminating device that can overcome at least one of the aforesaid drawbacks of the prior art.

According to the disclosure, an OLED illuminating device includes an OLED illuminating panel and at least one protective adhesive tape. The OLED illuminating panel has opposite first and second outer surfaces, and a peripheral surface that interconnects the first and second outer surfaces. The first outer surface has a transparent region and a peripheral region that surrounds the transparent region. The protective adhesive tape extends from the peripheral region to the second outer surface along the peripheral surface of the OLED illuminating panel.

### BRIEF DESCRIPTION OF THE DRAWINGS

Other features and advantages of the disclosure will become apparent in the following detailed description of the embodiment, with reference to the accompanying drawings, of which:

FIG. 1 is an exploded perspective view illustrating a conventional OLED illuminating panel and a plastic frame;

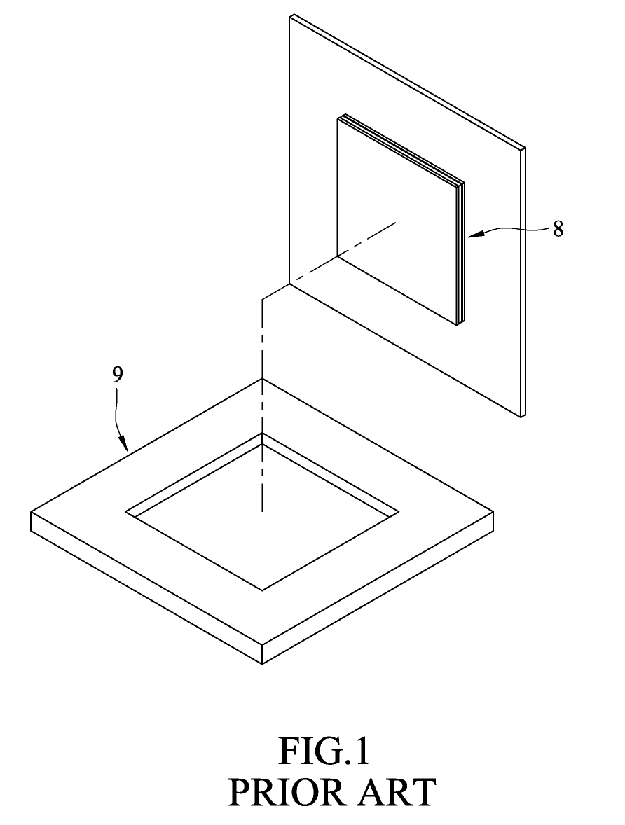

FIG. 2 is an assembled sectional view illustrating the conventional OLED illuminating panel disposed within the plastic frame;

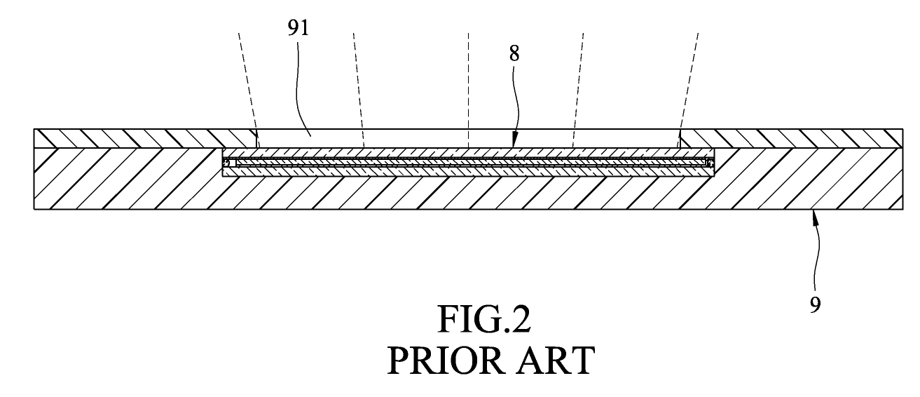

FIG. 3 is a fragmentary perspective view of an embodiment of an OLED illuminating device according to the disclosure;

FIG. 4 is a sectional view of the embodiment illustrating that a protective adhesive tape is adhered to an OLED illuminating panel;

FIG. 5 is a fragmentary sectional view illustrating that the embodiment is disposed in a light fixture; and

FIG. 6 is a perspective view illustrating a variation of the embodiment.

### DETAILED DESCRIPTION

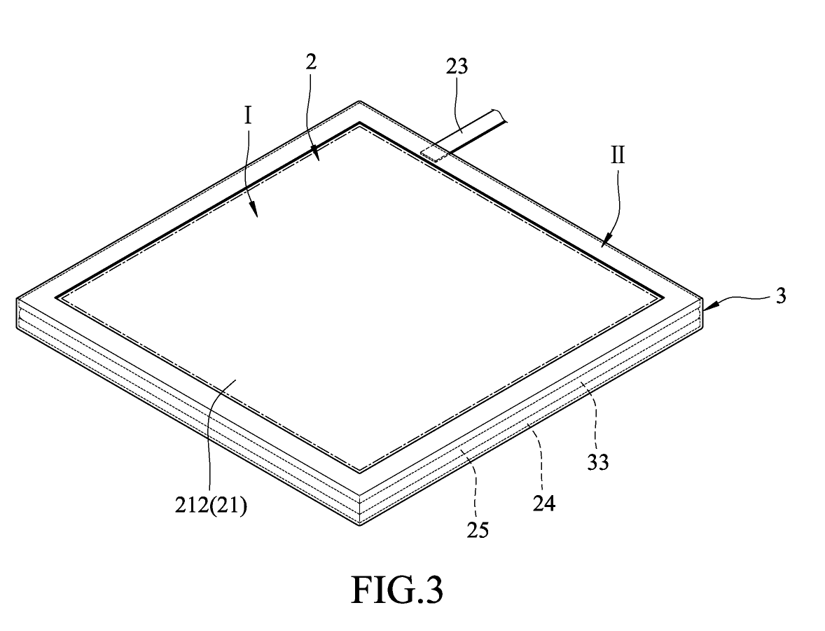

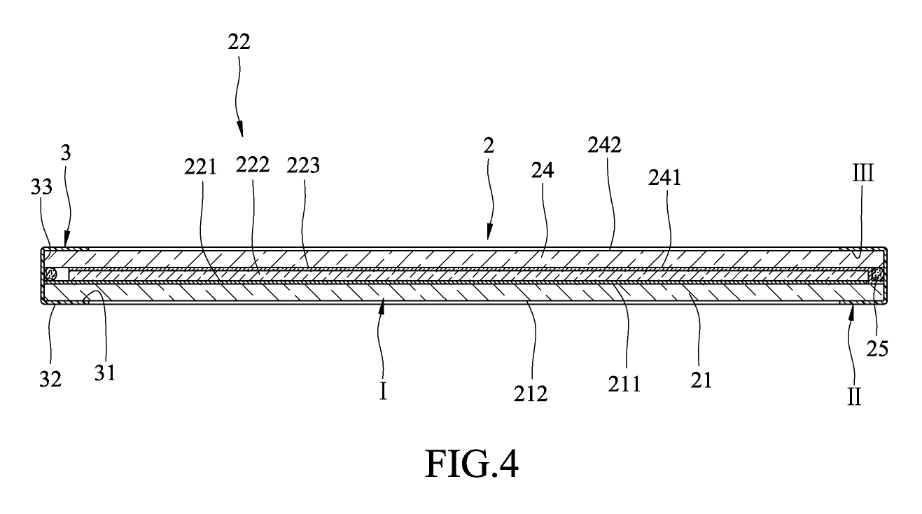

Referring to FIGS. 3, 4 and 5, an embodiment of an OLED illuminating device according to the disclosure is adapted to be disposed in a light fixture 1. The light fixture 1 includes a body 11 confining an accommodating space 12. The body 11 is formed with a through hole 13 that is in spatial communication with the accommodating space 12. The OLED illuminating device includes an OLED illuminating panel 2 and a protective adhesive tape 3.

The OLED illuminating panel 2 has opposite first and second outer surfaces 212, 242, and a peripheral surface 33 that interconnects the first and second outer surfaces 212, 242. The first outer surface 212 has a transparent region (I) and a peripheral region (II) that surrounds the transparent region (I).

In this embodiment, the OLED illuminating panel 2 is rectangular-shaped. However, the shape of the OLED illuminating panel 2 is not restricted to that in this embodiment, and may be designed differently based on actual needs.

In this embodiment, the OLED illuminating panel 2 includes a transparent substrate 21, an organic light-emitting unit 22, a flexible circuit board 23, a packaging cover 24, and an adhesive 25.

The transparent substrate 21 has the first outer surface 212, and a first inner surface 211 that is opposite to the first outer surface 212.

The organic light-emitting unit 22 is disposed on the first inner surface 211 of the transparent substrate 21, and has a first electrode layer 221, an organic illuminating multilayer 222 and a second electrode layer 223. The first electrode layer 221 is disposed on the first inner surface 211 of the transparent substrate 21. The organic illuminating multilayer 222 is layered on the first electrode layer 221 and is electrically connected to the first electrode layer 221. The second electrode layer 223 is placed on the organic illuminating multilayer 222 and is electrically connected to the organic illuminating multilayer 222.

The flexible circuit board 23 is electrically connected to the organic light-emitting unit 22, and extends outwardly.

The packaging cover 24 covers the second electrode layer 223 of the organic light-emitting unit 22, and has the second outer surface 242, and a second inner surface 241 opposite to the second outer surface 242 and facing the organic light-emitting unit 22.

The adhesive 25 connects the first inner surface 211 of the transparent substrate 21 and the second inner surface 241 of the packaging cover 24. The adhesive 25, the packaging cover 24, and the transparent substrate 21 cooperate with one another to package the organic light-emitting unit 22.

The organic illuminating multilayer 222 includes a hole injection layer, a hole transfer layer, an organic emissive layer, an electron transfer layer, and an electron injection layer sequentially formed in a direction from the first electrode layer 221 toward the second electrode layer 223. Since the structure of the organic illuminating multilayer 222 is not the focal point of this disclosure, it will not be further detailed hereinafter.

The transparent substrate 21 and the packaging cover 24 can be made of a flexible material or a non-flexible material. The flexible material maybe a polymer material selected from the group consisting of polyethylene terephthalate, polycarbonate, polyacrylic acid, and combinations thereof. The non-flexible material may be selected from glass, quartz and acrylic plate.

In this embodiment, the first electrode layer 221 of the organic light-emitting unit 22 is used as an anode, and the second electrode layer 223 of the organic light-emitting unit 22 is used as a cathode. The first electrode layer 221 and the second electrode layer 223 may be made of a transparent conductive material such as indium tin oxide, or a highly conductive metal, depending on actual needs.

Peripheries of the transparent substrate 21, the packaging cover 24 and the adhesive 25 constitute the peripheral surface 33.

The second outer surface 242 of the OLED illuminating panel 2 has an outer peripheral region (III) corresponding in position to the peripheral region (II) of the first outer surface 212. The protective adhesive tape 3 extends from the peripheral region (II) of the first outer surface 212 to the second outer surface 242 along the peripheral surface 33 of the OLED illuminating panel 2 to completely cover the peripheral surface 33, and preferably completely cover the peripheral region (II) of the first outer surface 212, the peripheral surface 33, and the outer peripheral region (III) of the second outer surface 242.

The protective adhesive tape 3 has an adhesive surface 31 adhered to the OLED illuminating panel 2, and an abutment surface 32 that is opposite to the adhesive surface 31 . The protective adhesive tape 3 has a thickness ranging from 5 μm to 1 mm. If the thickness of the protective adhesive tape 3 is less than 5 μm, the protective adhesive tape 3 may not be able to provide protection to the OLED illuminating panel 2 against damage from impact. If the thickness of the protective adhesive tape 3 is greater than 1 mm, the overall thickness of the OLED illuminating device may be too large. The abutment surface 32 of the protective adhesive tape 3 is roughened to increase a friction force between the protective adhesive tape 3 and the light fixture 1 such that the OLED illuminating panel 2 can be more stably disposed in the light fixture 1. Alternatively, the abutment surface 32 of the protective adhesive tape 3 is adhesive for achieving the same purpose, and the abutment surface 32 is designed to be less adhesive than the adhesive surface 31. If the abutment surface 32 is more adhesive than the adhesive surface 31, an adhesive force between the abutment surface 32 and the light fixture 1 will be larger than the adhesive force between the adhesive surface 31, and the OLED illuminating panel 2. As a result, the protective adhesive tape 3 may be separated from the OLED illuminating panel 2 when the OLED illuminating device is fit into or taken out of the light fixture 1, thereby causing inconvenience and lengthening the assembly process.

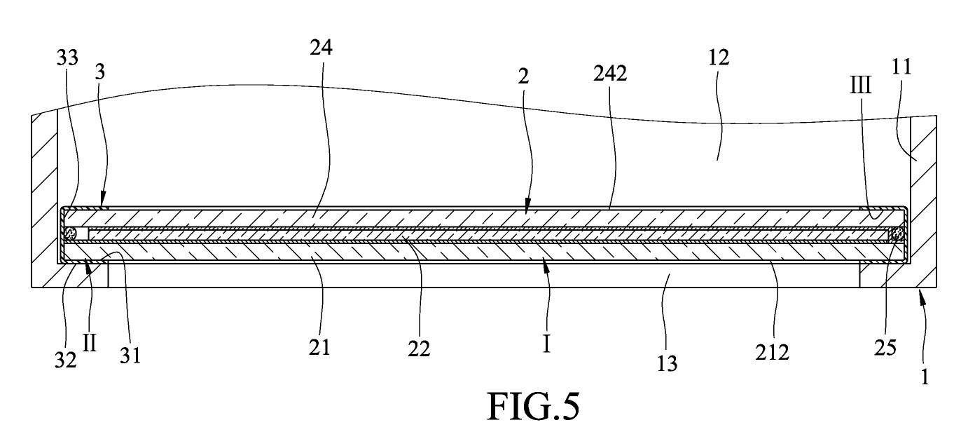

Referring to FIG. 5, the transparent region (I) of the OLED illuminating panel 2 corresponds in position to the through hole 13 of the light fixture 1, and the transparent substrate 21 is adjacent to the through hole 13. As such, the light emitted by the organic light-emitting unit 22 can transmit outwardly through the transparent substrate 21 and the through hole 13. A portion of the protective adhesive tape 3 which is adhered to the first outer surface 212 of the transparent substrate 21 is not exposed from the through hole 13, so as to improve the aesthetic appearance of the light fixture 1. Moreover, a portion of the abutment surface 32 of the protective adhesive tape 3 abuts against the body 11 of the light fixture 1.

Since the peripheral surface 33 of the OLED illuminating panel 2 of the OLED illuminating device is protected by the protective adhesive tape 3, the incidence of cracking of the OLED illuminating panel 2 can be effectively alleviated during assembly and transport of the OLED illuminating device. Furthermore, the abutment surface 32 of the protective adhesive tape 3 is designed to be capable of providing the friction force or the adhesive force to the body 11 of the light fixture 1 so that the OLED illumination panel 2 is more stably disposed in the light fixture 1. Consequently, relative movement between the OLED illuminating device and the light fixture 1 during transport, which may cause noise and even cracking of the OLED illumination panel 2, can be effectively alleviated.

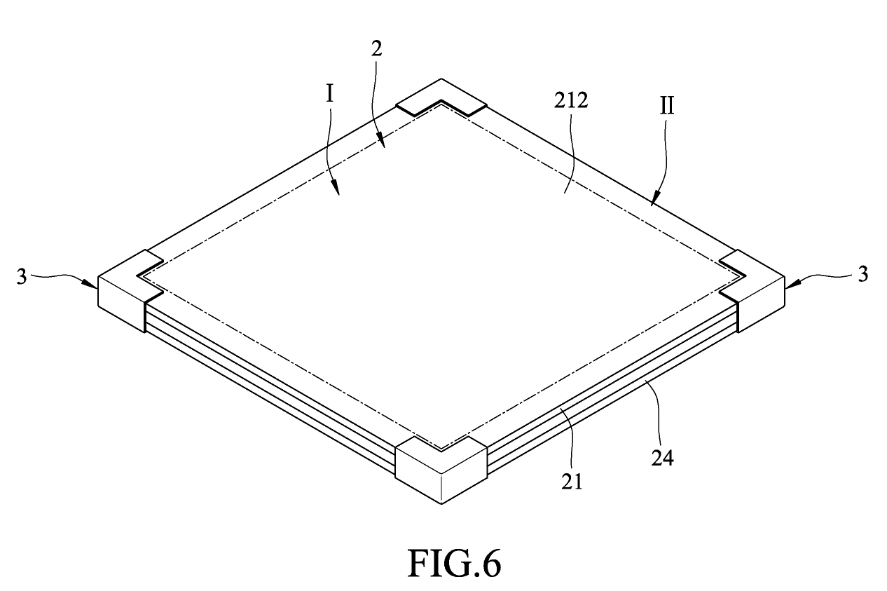

It is worth to mention that the configuration of the protective adhesive tape 3 is not limited to that shown in the aforementioned embodiment. Referring to FIG. 6, in a variation of the embodiment, the OLED illuminating device includes four of the protective adhesive tapes 3 that respectively cover four fragile corners of the OLED illuminating panel 2. This configuration can also achieve the aforementioned protective effect, and can further reduce the amount of the protective adhesive tape 3 used, thereby reducing the manufacturing costs of the OLED illuminating device.

To sum up, the OLED illuminating device according to the disclosure can alleviate the incidence of damage to the OLED illuminating panel 2 via the protective adhesive tape 3. Besides, since the thickness of the protective adhesive tape 3 is small, the size and the thickness of the OLED illuminating panel 2 is not significantly increased after being covered with the protective adhesive tape 3. The OLED illuminating device is hence still relatively compact.

While the disclosure has been described in connection with what is considered the exemplary embodiment, it is understood that this disclosure is not limited to the disclosed embodiment but is intended to cover various arrangements included within the spirit and scope of the broadest interpretation and equivalent arrangements.

What is claimed is:

1. An OLED illuminating device, comprising:
an OLED illuminating panel having opposite first and second outer surfaces, and a peripheral surface that interconnects said first and second outer surfaces, said first outer surface having a transparent region and a peripheral region that surrounds said transparent region; and
at least one protective adhesive tape that extends from said peripheral region to said second outer surface along said peripheral surface of said OLED illuminating panel.

2. The OLED illuminating device as claimed in claim 1, wherein said OLED illuminating panel is rectangular-shaped.

3. The OLED illuminating device as claimed in claim 2, comprising four of said protective adhesive tapes that respectively cover four corners of said OLED illuminating panel.

4. The OLED illuminating device as claimed in claim 3, wherein said protective adhesive tape has a thickness ranging from 5 μm to 1 mm.

5. The OLED illuminating device as claimed in claim 1, wherein said protective adhesive tape has an adhesive surface adhered to said OLED illuminating panel, and an abutment surface that is opposite to said adhesive surface.

6. The OLED illuminating device as claimed in claim 5, wherein said abutment surface of said protective adhesive tape is roughened.

7. The OLED illuminating device as claimed in claim 5, wherein said abutment surface of said protective adhesive tape is adhesive.

8. The OLED illuminating device as claimed in claim 7, wherein said abutment surface is less adhesive than said adhesive surface.

9. The OLED illuminating device as claimed in claim 8, wherein said protective adhesive tape has a thickness ranging from 5 μm to 1 mm.

10. The OLED illuminating device as claimed in claim 1, wherein said protective adhesive tape has a thickness ranging from 5 μm to 1 mm.

11. The OLED illuminating device as claimed in claim 1, wherein said second outer surface of said OLED illuminating panel has an outer peripheral region, said protective adhesive tape completely covering said peripheral region of said first outer surface, said peripheral surface and said outer peripheral region of said second outer surface.

12. The OLED illuminating device as claimed in claim 1, wherein said OLED illuminating panel includes
a transparent substrate having said first outer surface and a first inner surface that is opposite to said first outer surface,
an organic light-emitting unit that is disposed on said first inner surface of said transparent substrate, and
a packaging cover that covers said organic light-emitting unit, and that has said second outer surface, and a second inner surface facing said organic light-emitting unit.
